(19) United States
(12) Patent Application Publication
(10) Pub. No.: US 2004/0216660 A1
(43) Pub. Date: Nov. 4, 2004

(54) Method of forming high-quality quantum dots by using a strained layer

(76) Inventors: Jin Soo Kim, Daejeon-city (KR); Won Seok Han, Daejeon-city (KR); Jin Hong Lee, Daejeon-city (KR); Sung Ui Hong, Daejeon-city (KR); Ho Sang Kwack, Daejeon-city (KR); Dae Kon Oh, Daejeon-city (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/734,543

(22) Filed: Dec. 12, 2003

(30) Foreign Application Priority Data
May 1, 2003 (KR) 2003-27986

(51) Int. Cl. C30B 23/00; C30B 1/00; C30B 25/00; C30B 28/12; C30B 28/14

(52) U.S. Cl. 117/84; 117/2

(57) ABSTRACT

Provided is a method of forming quantum dots in which the quantum dots are formed on a thin InₓGa₁₋ₓAs strained layer. The In(Ga)As quantum dots can be applied to an active layer of an optical device such as a laser diode or an optical detector.

### BACKGROUND OF THE INVENTION

This application claims the priority of Korean Patent Application No. 2003-27986, filed on May 1, 2003, in the Korean Intellectual Property Office, the disclosure of which is incorporated herein in its entirety by reference.

1. Field of the Invention

The present invention relates to a method of forming quantum dots, and more particularly, to a method of forming high-quality quantum dots that can be used as an active layer of an optical device such as a laser diode or an optical detector.

2. Description of the Related Art

Recently, there has been considerable research into a Stranski-Krastanow growth method that forms quantum dots using a strain-relaxation process of a lattice-mismatched layer without a separate lithography process.

In particular, research into quantum dots has been actively carried out to apply quantum dots having a wavelength of about 1.3 μm and quantum dots having a wavelength of about 1.55 μm to the field of optical communications. Development of an In(Ga)As quantum dot laser diode, grown on a GaAs substrate that emits light having a wavelength of about 1.3 μm has been announced. In addition, research has been conducted into In(Ga)As quantum dots, grown from an InGaAsP layer or an InAl(Ga)As layer on a InP substrate, that emit light having a wavelength of about 1.55 μm (Hereinafter, when an element appears in brackets, it indicates that the element can be included or excluded. For instance, in the case of an InAl(Ga)As layer, this layer can be InAlAs or InAlGaAs).

However, when forming In(Ga)As quantum dots on a InAl(Ga)As layer, poor uniformity of the quantum dot causes there to be a wide full-width at half-maximum and a low light-emission intensity of photoluminescence generated by the resulting structure. Many problems arise in applying quantum dots to an active layer of an optical device.

### SUMMARY OF THE INVENTION

The present invention provides a method of forming quantum dots that have good uniformity, a narrow full-width at half-maximum of photoluminescence, and a strong light-emission intensity.

According to an aspect of the present invention, there is provided a buffer layer formed on an InP substrate. The buffer layer can be made of InAlAs, InAlGaAs, InP, InGaAsP or can be a hetrojunction layer of at least two of these four materials. Next, an InₓGa₁₋ₓAs strained layer is formed on the buffer layer. In the InₓGa₁₋ₓAs strained layer, “x” is preferably 0.05˜0.45, and the thickness of the layer is preferably in the range of be 0.5 nm˜10 nm. Finally, quantum dots are formed on the InₓGa₁₋ₓAs strained layer. The thickness of the In(Ga)As quantum dots is preferably 3˜10 monolayers.

In(Ga)As quantum dots formed according to a method of the present invention have dramatically improved uniformity, and a reduced full-width at half-maximum of photoluminescence, and a noticeably enhanced light-emission intensity.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1D are schematic diagrams illustrating a method of forming quantum dots using a strained layer according to the present invention;

FIGS. 2A and 2B are atomic force microscopy (AFM) images of a sample of quantum dots formed according to the prior art;

FIG. 2C is an atomic force microscopy (AFM) image of a sample of quantum dots formed according to the present invention;

FIG. 3A is a graph of intensity of photoluminescence verses wavelength at room temperature (300K) for a sample of quantum dots formed according to the present invention; and

FIG. 3B is a graph of photoluminescence versus photon energy at room temperature for a sample of quantum dots formed according to the present invention.

### DETAILED DESCRIPTION OF THE INVENTION

The present invention will now be described in detail with reference to the attached drawings. This invention may, however, be embodied in many different forms and should not be construed as being limited to the embodiments set forth herein; rather these embodiments are provided so that this disclosure will be thorough and complete, and will fully convey the concept of the invention to those skilled in the art. In the drawings, the size or thickness of films and regions are exaggerated for the clarity. It will also be understood that when a film is referred to as being “on” another film or a substrate, it can be directly on the other film or substrate, or intervening films may also be present.

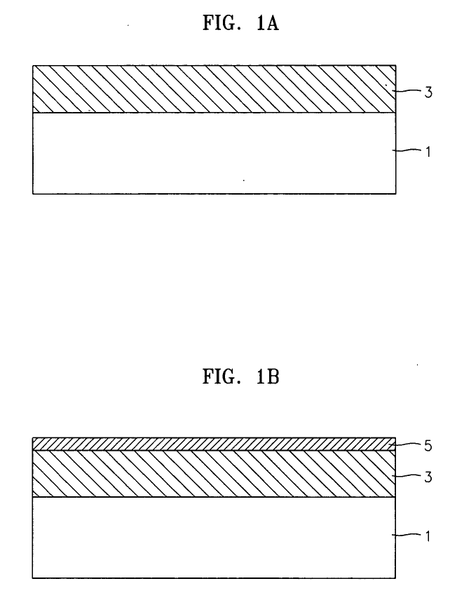

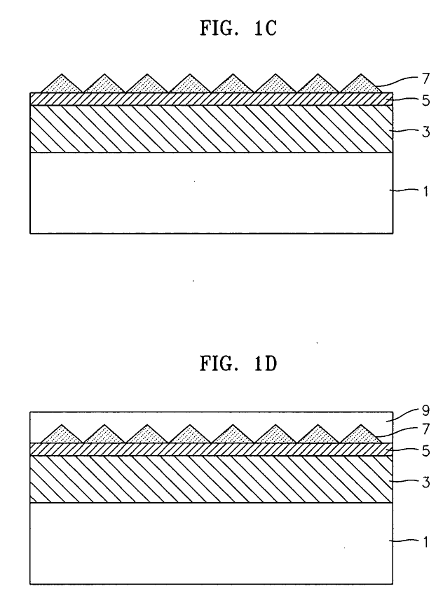

FIGS. 1A through 1D are schematic diagrams illustrating a method of forming quantum dots, using a strained layer according to the present invention.

Referring to FIG. 1A, a lattice-matched buffer layer 3 is formed on an InP substrate 1. The buffer layer 3 is formed of InAlAs, InAlGaAs, InP, InGaAsP, or is a hetrojunction layer of at least these four materials.

Referring to FIG. 1B, a thin InₓGa₁₋ₓAs strained layer 5 is then formed on the lattice-matched buffer layer 3. In the InₓGa₁₋ₓAs strained layer 5, “x” is in the range of 0.05˜0.45 and the thickness of the same strained layer 5 is in the range of 0.5 nm˜10 nm. The InₓGa₁₋ₓAs strained layer 5 is formed to change a surface structure of the lattice-matched buffer layer 3, for the purpose of achieving high uniformity of quantum dots, and to alter a strain energy that is necessary to grow quantum dots.

Referring to FIG. 1C, next, In(Ga)As quantum dots 7 are formed on the InₓGa₁₋ₓAs strained layer 5. The In(Ga)As quantum dots 7 are formed by metal organic chemical vapor depostion (MOCVD), molecular beam epitaxial (MBE), or chemical beam epitaxial (CBE). The thickness of the In(Ga)As quantum dots is in the range of 3˜10 monolayers. In the drawings, only one set of the InₓGa₁₋ₓAs strained layer 5 and the In(GA)As quantum dots 7 is illustrated. However, in alternative embodiments, 1 to 30 sets of the InₓGa₁₋ₓAs strained layer 5 and the In(Ga)As quantum dots 7 may be stacked on top of one another.

Finally, with reference to FIG. 1D, a capping layer 9 is formed on the In(Ga)As quantum dots 7 in order to fully cover the quantum dots 7. The capping layer 9 is formed of InAlAs, InAlGaAs, InP, InGaAsP or is a hetrojunction layer of at least two of these four materials.

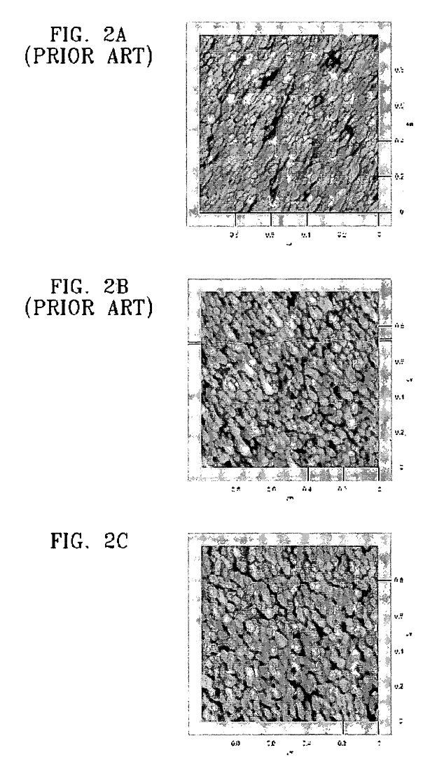

FIGS. 2A and 2B are atomic force microscopy (AFM) images of a sample of quantum dots formed according to the prior art.

FIG. 2A is a surface image of a sample of the In(Ga)As quantum dots on an InAlAs buffer layer formed on a InP substrate according to the prior art. As shown in FIG. 2A, a shape of the In(Ga)As quantum dots are elongated [1-10] direction. This shape is caused by the surface structure of the InAlAs alloy.

FIG. 2B is a surface image of a sample grown of the In(Ga)As quantum dots formed on the InAlGaAs buffer layer formed on the InP substrate according to the prior art. As illustrated in FIG. 2B, it can be seen that the In(Ga)As quantum dots are a bit larger and more spherical in comparison to the sample of FIG. 2A. The reason is that InAlGaAs builds a different type of surface due to diffusion of Ga and Al, and a difference of a sticking coefficient.

FIG. 2C is a surface image of a sample grown of the In(Ga)As quantum dots on a thin InₓGa₁₋ₓAs strained layer formed on a InAlGaAs buffer layer formed on a InP substrate according to the present invention. It can be seen that the In(Ga)As quantum dots are a bit larger and more spherical than the prior art quantum dots shown in FIGS. 2A and 2B. Furthermore, the uniformity of the In(Ga)As quantum dots of the present invention is noticeably enhanced. In fact, the In(Ga)As quantum dots formed according to the present invention are almost ultramicro-structured quantum dots having a three dimensional quantum bound effect.

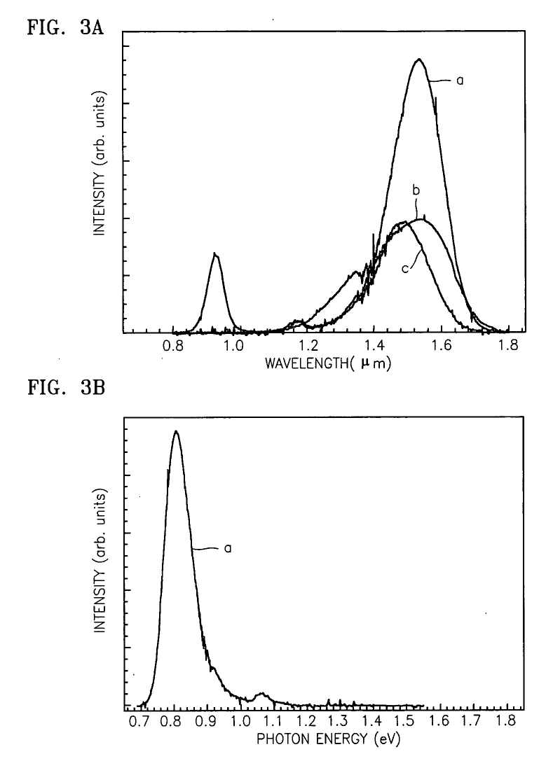

FIG. 3A is a graph of intensity of photoluminescence, versus wavelength at room temperature (300K) for a sample of quantum dots formed according to the present invention. FIG. 3B is also a graph of intensity of photoluminescence versus photon energy at room temperature for a sample of quantum dots formed according to the present invention.

In FIGS. 3A and 3B, data labeled “a” represents the present invention in which the In(Ga)As quantum dots are grown on the InₓGa₁₋ₓAs strained layer formed on the InAlGaAs buffer layer formed on the InP substrate. The data marked “b” corresponds to the prior art in which the In(Ga)As quantum dots grown on the InAlAs buffer layer formed on the InP substrate, and the data labeled “c” corresponds to the prior art in which the In(Ga)As quantum dot are grown on the InAlGaAs buffer layer formed on the InP substrate.

As illustrated in FIGS. 3A and 3B, a full-width at half-maximum of photoluminescence and intensity at room temperature of the In(Ga)As quantum dots grown on the InₓGa₁₋ₓAs strained layer exhibit great improvement over the prior art.

Furthermore, the sample of the In(Ga)As quantum dots formed on the InAlAs layer has a 104 meV full-width at half-maximum of photoluminescence at room temperature. And the sample of the In(Ga)As quantum dots formed on the InAlGaAs layer according to the prior art has a 76 meV full-width at half-maximum of photoluminescence at room temperature.

However, as shown in FIG. 3B, the sample of the In(Ga)As quantum dots formed on the InₓGa₁₋ₓAs strained layer has a 64 meV full-width at half-maximum of photoluminescence at room temperature according to the present invention. This result, which may be brought about by increased uniformity of the quantum dots, corresponds with the result of the AFM in FIG. 2. Moreover, the intensity of the sample formed according to in the present invention is about 2.5 times stronger than the intensities of the samples based on the prior art.

As described above, in the present invention, In(Ga)As quantum dots are formed on a thin InₓGa₁₋ₓAs strained layer formed on an InAl(Ga)As buffer layer on the InP substrate. A sample made in this way has greatly increased uniformity, a reduced full-width at half-maximum of photoluminescence, and a dramatically enhanced intensity. Therefore, if the In(Ga)As quantum dots formed according to the present invention are applied to an active layer of an optical device, such as a light-emission device, for example a laser diode, or an optical detector, the characteristics of the optical device are improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming quantum dots, the method comprising:
an InₓGa₁₋ₓAs strained layer formed on a buffer layer; and
In(Ga)As quantum dots formed on the InₓGa₁₋ₓAs strained layer.

2. The method of forming quantum dots of claim 1, wherein the buffer layer is made of InAlAs, InAlGaAs, InP, InGaAsP or is a hetrojunction layer of at least two of these four materials.

3. The method of forming quantum dots of claim 1, wherein in the InₓGa₁₋ₓAs strained layer, “x” is 0.05˜0.45.

4. The method of forming quantum dots of claim 1, wherein the thickness of the InₓGa₁₋ₓAs strained layer is in a range of 0.5 nm˜10 nm.

5. The method of forming quantum dots of claim 1, wherein In(Ga)As quantum dots are formed by metal organic chemical vapor depostion (MOCVD), molecular beam epitaxial (MBE), or chemical beam epitaxial (CBE).

6. The method of forming quantum dots of claim 1, wherein the thickness of the InₓGa₁₋ₓAs quantum dots is 3˜10 monolayers.

7. The method of forming quantum dots of claim 1, wherein the InₓGa₁₋ₓAs strained layer 5 and the In(Ga)As quantum dots 7 can be stacked 1 to 30 sets on top of one another.
